(19) United States
(12) Patent Application Publication
(10) Pub. No.: US 2025/0293646 A1
(43) Pub. Date: Sep. 18, 2025

(54) AMPLIFIER WITH HARMONIC CANCELLATION FEEDBACK CIRCUIT TO IMPROVE LINEARITY

(71) Applicant: QUALCOMM Incorporated, San Diego, CA (US)

(72) Inventors: Milad FROUNCHI, Santa Clara, CA (US); Khan Md Zobayer HASSAN, Mountain View, CA (US); Kamal AGGARWAL, Pleasanton, CA (US)

(21) Appl. No.: 18/602,621

(22) Filed: Mar. 12, 2024

(51) Int. Cl. H03F 3/19

(52) U.S. Cl. CPC H03F 3/19; H03F 2200/171; H03F 2200/451

(57) ABSTRACT

An apparatus including: an amplifier configured to amplify an input radio frequency (RF) signal having a fundamental frequency to generate an output RF signal including the fundamental frequency and a harmonic of the fundamental frequency; a common mode sense circuit configured to generate an output common mode signal related to the output RF signal; a harmonic cancellation feedback circuit configured to generate a common mode feedback signal based on the output common mode signal; and a common mode injection circuit configured to inject the common mode feedback signal into the amplifier, wherein the common mode feedback signal reduces the harmonic in the output RF signal.

### FIELD

Aspects of the present disclosure relate generally to amplifiers (such as, power amplifiers (PAs), driver amplifiers, or others), and in particular, to an amplifier with a harmonic cancellation feedback circuit to improve linearity.

### BACKGROUND

A power amplifier (PA) is typically used in a transmitter or transceiver to amplify an input radio frequency (RF) signal to generate an output RF signal for wireless transmission via at least one antenna. In certain applications, the frequency constituents (e.g., the fundamental, harmonics, and other frequencies) of the output RF signal are of interest, for example, to meet spectrum mask compliance, error vector magnitude (EVM) data requirements, and operational reliability for the PA.

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to an apparatus. The apparatus includes: an amplifier configured to amplify an input radio frequency (RF) signal having a fundamental frequency to generate an output RF signal including the fundamental frequency and a harmonic of the fundamental frequency; a common mode sense circuit configured to generate an output common mode signal related to the output RF signal; a harmonic cancellation feedback circuit configured to generate a common mode feedback signal based on the output common mode signal; and a common mode injection circuit configured to inject the common mode feedback signal into the amplifier, wherein the common mode feedback signal reduces the harmonic in the output RF signal.

Another aspect of the disclosure relates to a method. The method includes amplifying an input radio frequency (RF) signal including a fundamental frequency to generate an output RF signal including the fundamental frequency and a harmonic of the fundamental frequency; sensing an output common mode signal associated with the output RF signal; processing the output common mode signal to generate a common mode feedback signal; and injecting the common mode feedback signal such that it combines with the input RF signal, the common mode feedback signal reducing the harmonic in the output RF signal.

Another aspect of the disclosure relates to an apparatus. The apparatus includes means for amplifying an input radio frequency (RF) signal having a fundamental frequency to generate an output RF signal including the fundamental frequency and a harmonic of the fundamental frequency; means for sensing an output common mode signal associated with the output RF signal; means for processing the output common mode signal to generate a common mode feedback signal; and means for injecting the common mode feedback signal such that it combines with the input RF signal, the common mode feedback signal reducing the harmonic in the output RF signal.

Another aspect of the disclosure relates to a wireless communication device. The wireless communication device includes: a modem configured to generate a transmit baseband signal; a local oscillator (LO) configured to generate one or more transmit LO signals; one or more frequency upconverting stages configured to frequency upconvert the transmit baseband signal to generate a transmit radio frequency (RF) signal based on the one or more transmit LO signals, respectively; an amplifier configured to amplify the transmit RF signal having a fundamental frequency to generate a transmit output RF signal including the fundamental frequency and a harmonic of the fundamental frequency; a common mode sense circuit configured to generate an output common mode signal related to the transmit output RF signal; a harmonic cancellation feedback circuit configured to generate a common mode feedback signal based on the output common mode signal; a common mode injection circuit configured to inject the common mode feedback signal into the amplifier, wherein the common mode feedback signal reduces the harmonic in the transmit output RF signal; and at least one antenna configured to wirelessly radiate the transmit output RF signal.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1 illustrates a block diagram of an example power amplifier (PA) in accordance with an aspect of the disclosure.

FIG. 2 illustrates a block diagram of an example power amplifier (PA) circuit in accordance with another aspect of the disclosure.

FIG. 3A illustrates a block diagram of another example power amplifier (PA) circuit in accordance with another aspect of the disclosure.

FIG. 3B illustrates a block diagram of an example second harmonic cancellation feedback circuit in accordance with another aspect of the disclosure.

FIG. 3C illustrates a block diagram of another example second harmonic cancellation feedback circuit in accordance with another aspect of the disclosure.

FIG. 3D illustrates a block diagram of another example second harmonic cancellation feedback circuit in accordance with another aspect of the disclosure.

FIG. 4 illustrates a block diagram of another example power amplifier (PA) circuit in accordance with another aspect of the disclosure.

FIG. 5 illustrates a block diagram of another example power amplifier (PA) circuit in accordance with another aspect of the disclosure.

FIG. 6 illustrates a block diagram of another example power amplifier (PA) circuit in accordance with another aspect of the disclosure.

FIG. 7 illustrates a block diagram of another example power amplifier (PA) circuit in accordance with another aspect of the disclosure.

FIG. 8 illustrates a block diagram of another example power amplifier (PA) circuit in accordance with another aspect of the disclosure.

FIG. 9 illustrates a block diagram of another example power amplifier (PA) circuit in accordance with another aspect of the disclosure.

FIG. 10 illustrates a block diagram of another example power amplifier (PA) circuit in accordance with another aspect of the disclosure.

FIG. 11 illustrates a block diagram of an example wireless communication device in accordance with another aspect of the disclosure.

FIG. 12 illustrates a flow diagram of an example method of reducing a harmonic constituent of an output radio frequency (RF) signal of a power amplifier (PA) in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

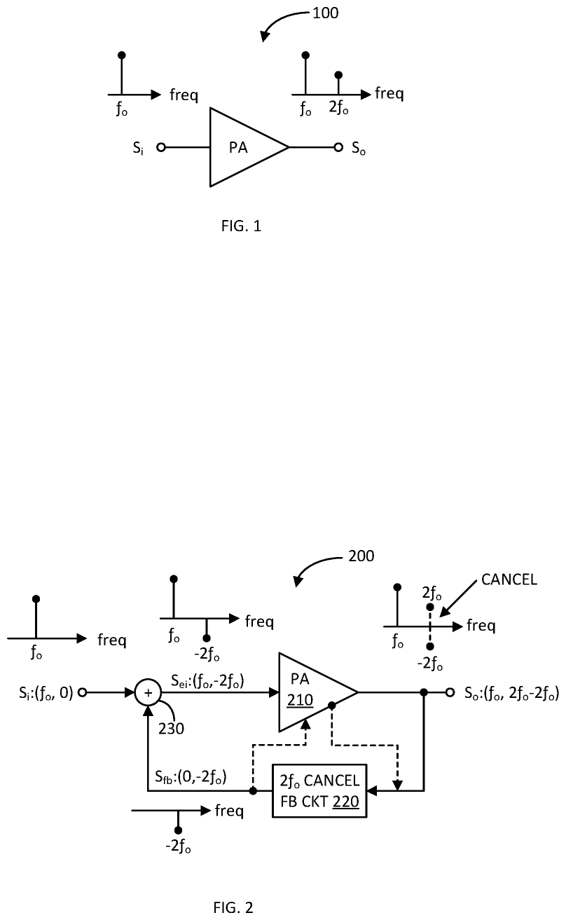

FIG. 1 illustrates a block diagram of an example power amplifier (PA) 100 in accordance with an aspect of the disclosure. Although a PA is used to exemplify the concepts herein, it shall be understood that the concepts described herein shall apply to other amplifiers, such as driver amplifiers and others. The PA 100 is configured to receive and amplify an input radio frequency (RF) signal Sᵢ to generate an output RF signal Sₒ. The input RF signal Sᵢ includes a fundamental frequency fₒ, (e.g., such as an operational frequency, a carrier frequency, or a modulated carrier having some bandwidth defined by a fundamental frequency) as indicated in a corresponding frequency spectrum graph shown near the input of the PA 100. Due to the non-linearity of the PA 100, the frequency constituents of the output RF signal Sₒ includes the fundamental frequency fₒ and at least a second harmonic frequency 2fₒ, as indicated in an output signal frequency spectrum graph shown near the output of the PA 100.

In certain applications, the second harmonic 2fₒ in the output RF signal Sₒ may be undesirable for various reasons. For example, certain governmental and/or regulatory bodies (e.g., such as the Federal Communications Commission (FCC) in the United States) may place restrictions on the frequencies or bandwidth in the wireless transmission of the output RF signals Sₒ, typically referred to as a spectrum mask. In some cases, the second harmonic 2fₒ in the output RF signal Sₒ may violate the spectrum mask. Further, the second harmonic 2fₒ may cause error in data symbol constellation present in the output RF signal Sₒ, typically characterized in an error vector magnitude (EVM) metric. Additionally, the second harmonic 2fₒ of the output RF signal Sₒ may adversely impact the reliability of the PA 100. Thus, in certain cases, it may be desirable to reduce the second harmonic 2fₒ in the output RF signal Sₒ.

FIG. 2 illustrates a block diagram of an example power amplifier (PA) circuit 200 in accordance with another aspect of the disclosure. The PA circuit 200 includes a power amplifier (PA) 210, a second harmonic 2fₒ cancellation feedback circuit 220, and a signal combining component 230. The signal combining component 230 includes a first input configured to receive an input radio frequency (RF) signal Sᵢ, a second input coupled to an output of the second harmonic 2fₒ cancellation feedback circuit 220, and an output coupled to an input of the PA 210.

As mentioned, the first input of the combining component 230 is configured to receive the input RF signal Sᵢ. The second input of the combining component 230 is configured to receive a feedback RF signal S_{fb} from the second harmonic 2fₒ cancellation feedback circuit 220. The combining component 230 is configured to generate an effective input RF signal Sₑᵢ for the PA 210, which may be related to a sum of the input RF signal Sᵢ and the feedback RF signal S_{fb}. The PA 210 is configured to amplify the effective input RF signal Sₑᵢ to generate an output RF signal Sₒ. The second harmonic 2fₒ cancellation feedback circuit 220 is configured to generate the feedback RF signal S_{fb} based on the output RF signal Sₒ.

With further reference to the frequency spectrum graphs shown proximate the corresponding signals, the input RF signal Sᵢ includes a carrier (e.g., which may be modulated with data or information) cycling at a fundamental frequency fₒ. As discussed further herein, the feedback RF signal S_{f}v includes a second harmonic frequency −2fₒ phase-shifted Δϕ (e.g., substantially 180°) with respect to a phase of a second harmonic 2fₒ in the output RF signal Sₒ generated due to the non-linearity of the PA 210. Accordingly, the PA effective input RF signal Sₑᵢ includes the fundamental frequency fₒ from the input RF signal Sᵢ and the phase-shifted second harmonic −2fₒ of the feedback RF signal S_{fb}. The output RF signal Sₒ includes the fundamental frequency fₒ, the non-linear generated second harmonic 2fₒ, and the phase-shifted harmonic frequency −2fₒ.

As discussed further herein, the second harmonic 2fₒ cancellation feedback circuit 220 is configured to generate the feedback RF signal S_{fb} so as to reduce the non-linear generated second harmonic 2fₒ in the output RF signal Sₒ by at least partial cancellation with the phase-shifted second harmonic frequency −2fₒ(e.g., 2fₒ−2fₒ). Thus, the output RF signal Sₒ may primarily include the fundamental frequency fₒ with a substantially reduced second harmonic 2fₒ. Although, in the example implementations described herein, the cancellation feedback circuit 220 is configured to reduce the second harmonic 2fₒ in the output RF signal Sₒ, it shall be understood that the cancellation feedback circuit 220 may be configured to reduce other non-linear generated harmonic components, such as other even harmonics (e.g., 4fₒ, 6fₒ, etc.).

Although in the example PA circuit 200, the combining component 230 is shown separate and upstream of the PA 210, as further exemplified herein, the PA 210 may internally include the combining component as indicated by the dashed arrow line from the second harmonic 2fₒ cancellation feedback circuit 220 into the PA 210 (See e.g., FIG. 9).

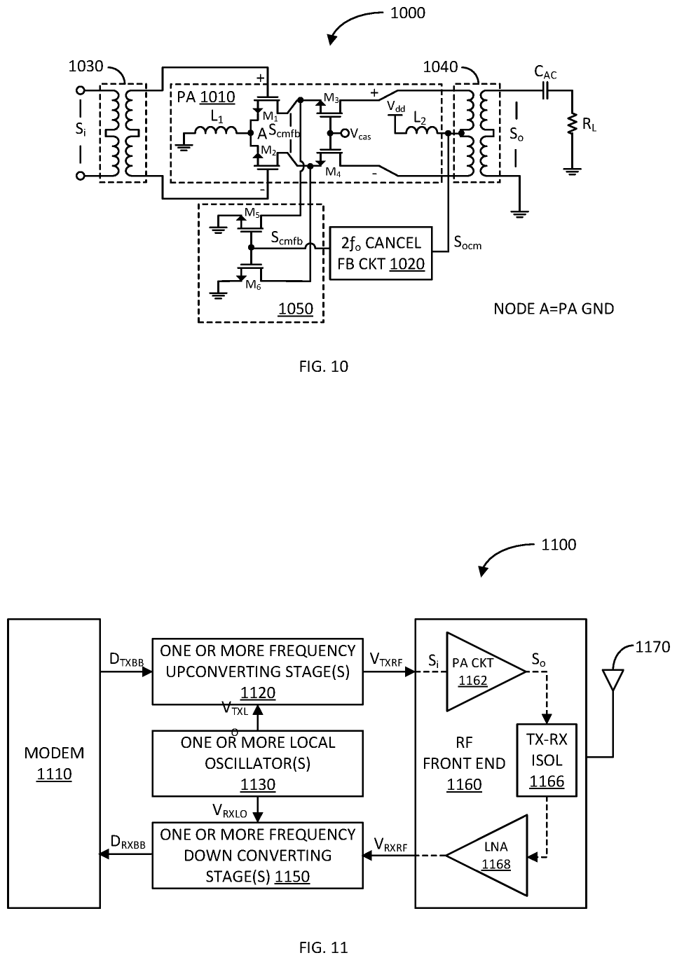

Similarly, although in this example, the output of the PA 210 provides the input signal for the second harmonic 2fₒ cancellation feedback circuit 220, it shall be understood that the input signal for the second harmonic 2fₒ cancellation feedback circuit 220 may be internally generated by the PA 210 (See e.g., FIG. 10). The following describes various example implementations of the PA circuit 200.

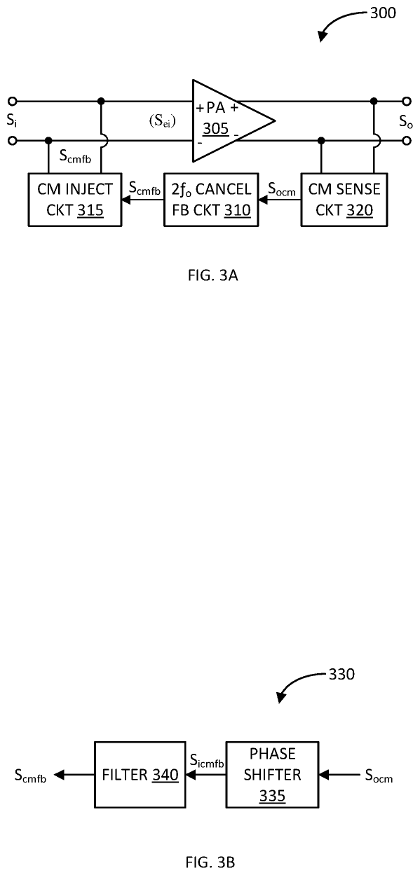

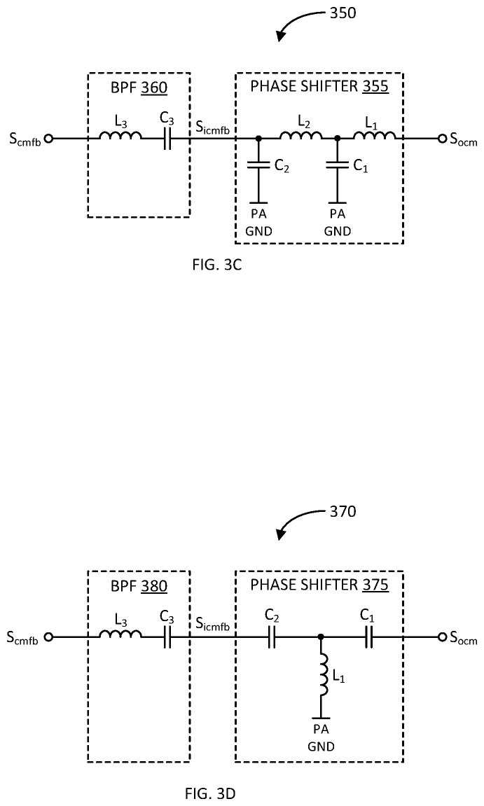

FIG. 3A illustrates a block diagram of another example power amplifier (PA) circuit 300 in accordance with another aspect of the disclosure. The PA circuit 300 includes a differential power amplifier (PA) 305, a common mode sense circuit 320, a second harmonic 2fₒ cancellation feedback circuit 310, and a common mode injection circuit 315. The PA 305 includes a differential input (+/−) configured to receive an input radio frequency (RF) signal Sᵢ and a common mode feedback signal S_{cmfb}. The input RF signal Sᵢ includes the fundamental frequency fₒ, and the common mode feedback signal S_{cmfb} includes the phase-shifted second harmonic frequency −2fₒ. Thus, with reference to PA circuit 200, the effective input RF signal Sₑᵢ (e.g., which may be differential in this case) for the PA 305 may include a sum or combination of the fundamental frequency fₒ and the phase-shifted second harmonic −2fₒ.

The PA 305 is configured to differentially amplify the effective input RF signal Sₑᵢ to generate a differential output RF signal Sₒ at a differential output (+/−). Due to the non-linearity of the PA 305, the PA 305 generates a second harmonic 2fₒ from the fundamental frequency fₒ. Thus, the output RF signal Sₒ includes the fundamental frequency fₒ, the non-linear generated second harmonic 2fₒ, and the phase-shifted second harmonic −2fₒ. As previously discussed, the non-linear generated second harmonic 2fₒ, and the phase-shifted second harmonic −2fₒ may have a phase difference Δϕ effectuated by the second harmonic 2fₒ cancellation feedback circuit 310. Thus, the second harmonic in the output RF signal Sₒ may be substantially reduced due to at least partial cancellation of the non-linear generated second harmonic 2fₒ by the phase-shifted second harmonic −2fₒ.

With regard to generating the common mode feedback signal S_{cmfb}, the common mode sense circuit 320 is configured to sense an output common mode signal S_{ocm} associated with the output RF signal Sₒ. The second harmonic 2fₒ cancellation feedback circuit 310 is configured to generate the common mode feedback signal S_{cmfb} based on the output common mode signal S_{ocm}. The common mode injection circuit 315 is configured to inject the common mode feedback signal S_{cmfb} into the differential input of the PA 305 such that the common mode feedback signal S_{cmfb} combines with the input RF signal Sᵢ to generate the effective input signal Sₑᵢ. As discussed in more detail herein, the second harmonic 2fₒ cancellation feedback circuit 310 is configured to process the output common mode signal S_{ocm} to generate the common mode feedback signal S_{cmfb} so as to effectuate at least partial second harmonic cancellation at the differential output of the PA 305 to reduce the second harmonic 2fₒ in the output RF signal Sₒ.

FIG. 3B illustrates a block diagram of an example second harmonic cancellation feedback circuit 330 in accordance with another aspect of the disclosure. The second harmonic cancellation feedback circuit 330 may be an example implementation of the second harmonic cancellation feedback circuits 220 and 310 of PA circuits 200 and 300, respectively.

The second harmonic cancellation feedback circuit 330 includes a phase shifter 335 and a filter 340. The phase shifter 335 is configured to phase shift (e.g., Δϕ˜180°) the output common mode signal S_{ocm} to, for example, generate the phase-shifted second harmonic −2fₒ in an intermediate common mode feedback signal S_{icmfb}. The filter 340, which may be implemented as a band pass filter (BPF) or high pass filter (HPF), is configured to filter the intermediate common mode feedback signal S_{imfb} to substantially remove the fundamental frequency fₒ and maintain the phase-shifted second harmonic −2fₒ in the common mode feedback signal S_{cmfb} for second harmonic cancellation in the output RF signal Sₒ. The filter 340 (e.g., an active filter), the phase shifter 335, and/or other component (e.g., an amplifier, attenuator or other) may be configured to adjust the amplitude of the phase-shifted second harmonic −2fₒ so that it is substantially equal and opposite to the amplitude of the non-linear second harmonic 2fₒ to improve the reduction or cancellation of the non-linear second harmonic −2fₒ. Although, in this example, the phase shifter 335 precedes the filter 340 with regard to processing the mentioned signals, it shall be understood that the phase shifter 335 may follow the filter 340 in this regard.

FIG. 3C illustrates a block diagram of another example second harmonic cancellation feedback circuit 350 in accordance with another aspect of the disclosure. The second harmonic cancellation feedback circuit 350 may be an example implementation of the second harmonic cancellation feedback circuit 330 previously discussed. In particular, the second harmonic cancellation feedback circuit 350 includes a phase shifter 355 followed by a band pass filter (BPF) 360.

The phase shifter 355 may be implemented as a right-hand transmission-line (RHTL) phase shifter (e.g., an L-C-L T-network). In this regard, the phase shifter 355 includes a first inductor L₁ coupled in series with a second inductor L₂ between an input configured to receive the output common mode signal S_{ocm} and an output configured to generate the intermediate common mode feedback signal S_{icmfb}. Additionally, the phase shifter 355 may include a first capacitor C₁ including a first terminal coupled between the first and second inductors L₁ and L₂, and a second terminal coupled to PA ground (identified as node “A” in other figures), which may be different than actual ground used by other circuits, such as transformers and load R_{L}). Further, the phase shifter 355 may include a second capacitor C₂ coupled between the output of the phase shifter 355 and PA ground. Any one or more of these elements L₁, L₂, C₁, and C₂ may be made variable or programmable to effectuate the desired phase shift A in the output common mode signal S_{ocm} for second harmonic cancellation, as previously discussed.

The BPF 360, in turn, includes a third capacitor C₃ coupled in series with a third inductor L₃ between the output of the phase shifter 355 and the output of the BPF 360, where the common mode feedback signal S_{cmfb} may be generated. Any one or more of these elements L₃ and C₃ may be made variable or programmable to substantially remove the fundamental frequency fₒ from while maintaining the phase-shifted second harmonic −2fₒ in the common mode feedback signal S_{cmfb}.

FIG. 3D illustrates a block diagram of another example second harmonic cancellation feedback circuit 370 in accordance with another aspect of the disclosure. The second harmonic cancellation feedback circuit 370 may be another example implementation of the second harmonic cancellation feedback circuit 330 previously discussed. In particular, the second harmonic cancellation feedback circuit 370 includes a phase shifter 375 followed by a band pass filter (BPF) 380.

The phase shifter 375 may be implemented as a left-hand transmission-line (LHTL) phase shifter (e.g., a C-L-C T-network). In this regard, the phase shifter 375 may include a first inductor C₁ coupled in series with a second inductor C₂ between an input configured to receive the output common mode signal S_{ocm} and an output configured to generate the intermediate common mode feedback signal S_{icmfb}. Additionally, the phase shifter 375 may include an inductor L₁ including a first terminal coupled between the first and second capacitors C₁ and C₂, and a second terminal coupled to PA ground. Any one or more of these elements L₁, C₁, and C₂ may be made variable or programmable to effectuate the desired phase shift A in the output common mode signal S_{ocm} for second harmonic cancellation, as previously discussed. The BPF 380 may be implemented per the BPF 360 of the second harmonic cancellation feedback circuit 350 previously discussed.

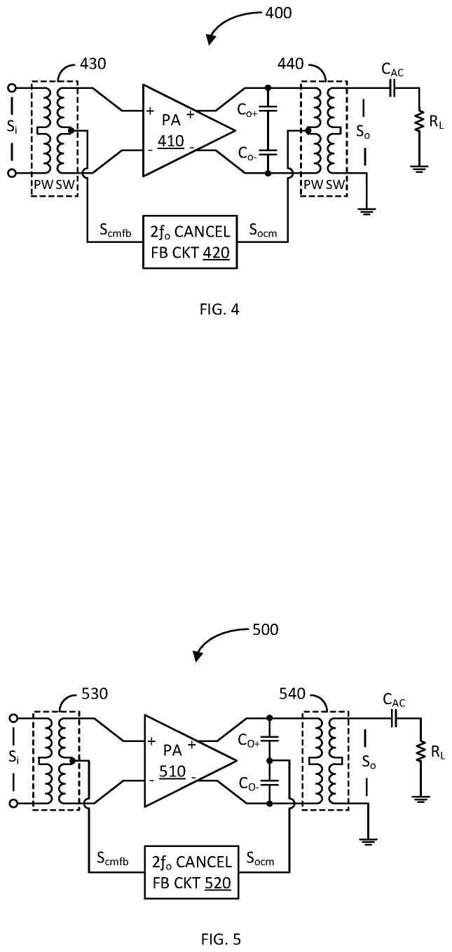

FIG. 4 illustrates a block diagram of another example power amplifier (PA) circuit 400 in accordance with another aspect of the disclosure. The PA circuit 400 may be an example implementation of the PA circuit 300 previously discussed. The PA circuit 400 includes an input transformer 430 (sometimes referred to as a balun) including a primary winding (PW) and a secondary winding (SW). The transformer 430 is configured to receive an input differential radio frequency (RF) signal Sᵢ across its primary winding (PW). The secondary winding (PW) of the transformer 430 is coupled across a differential input (+/−) of a differential power amplifier (PA) 410.

The PA circuit 400 may further include one or more output capacitors Cₒ₊ and Cₒ₋, which may be coupled in series across a differential output (+/−) of the PA 410. Additionally, the PA circuit 400 includes an output transformer 440 (e.g., a balun) including a primary winding (PW) and a secondary winding (SW). The primary winding (PW) is also coupled across the differential output (+/−) of the PA 410. The PA 410 is configured to amplify the input differential RF signal Sᵢ to generate an output differential RF signal Sₒ, which may be produced across the capacitors Cₒ₊ and Cₒ₋, and primary and secondary windings of the output transformer 440, where an end of the secondary winding (SW) may be coupled to actual ground. The output differential RF signal Sₒ may be provided to a load, such as an antenna or further transmit circuitry (represented as a resistive load R_{L}), via a series alternating current (AC) coupled capacitor C_{AC} situated between the secondary winding (SW) of the transformer 440 and actual ground.

With regard to developing a feedback signal for second harmonic cancellation at the differential output (+/−) of the PA 410, the PA circuit 400 includes a second harmonic cancellation feedback circuit 420 including an input coupled to an intermediate tap (e.g., a center or other tap) situated between opposite ends of the primary winding (PW) of the output transformer 440. The intermediate tap of the primary winding (PW) is configured to generate an output common mode signal (e.g., voltage) S_{ocm} associated with the differential output RF signal Sₒ. Thus, the coupling of the input of the second harmonic cancellation feedback circuit 420 to the intermediate tap of the output primary winding (PW) constitutes a common mode sense circuit (e.g., by voltage sensing) in a similar vein as the common mode sense circuit 320 of PA circuit 300 previously described.

Similarly, the second harmonic cancellation feedback circuit 420 is configured to generate a common mode feedback signal S_{cmfb} based on the output common mode signal S_{ocm}, as previously discussed with reference to PA circuit 300 and example second harmonic cancellation feedback circuits 330, 350, and 370. The second harmonic cancellation feedback circuit 420 includes an output coupled to an intermediate tap (e.g., center or other) situated between opposite ends of the secondary winding (SW) of the input transformer 430. Via the intermediate tap of the input secondary winding (SW), the common mode feedback signal S_{cmfb} may be injected (e.g., by voltage injection) into the differential input (+/−) of the PA 410 in a similar vein as the common mode injection circuit 315 of PA circuit 300 previously described.

FIG. 5 illustrates a block diagram of another example power amplifier (PA) circuit 500 in accordance with another aspect of the disclosure. The PA circuit 500 may be an example implementation of the PA circuit 300 previously discussed. The PA circuit 500 may be an example variation of the example PA circuit 400 previously discussed. Accordingly, components of the PA circuit 500 same/similar to corresponding components of PA circuit 400 previously discussed in detail are numbered the same with the exception that the most significant digit is a “5” in PA circuit 500 instead of a “4” in PA circuit 400.

The PA circuit 500 differs from the PA circuit 400 in that the second harmonic cancellation feedback circuit 520 includes an input coupled to a node between the output capacitors Cₒ₊ and Cₒ₋ to sense the output common mode signal (e.g., by voltage sensing) S_{ocm}. Thus, the coupling of the input of the second harmonic cancellation feedback circuit 520 to the node between the output capacitors Cₒ₊ and Cₒ₋ constitutes a common mode sense circuit in a similar vein as the common mode sense circuit 320 of PA circuit 300 previously described.

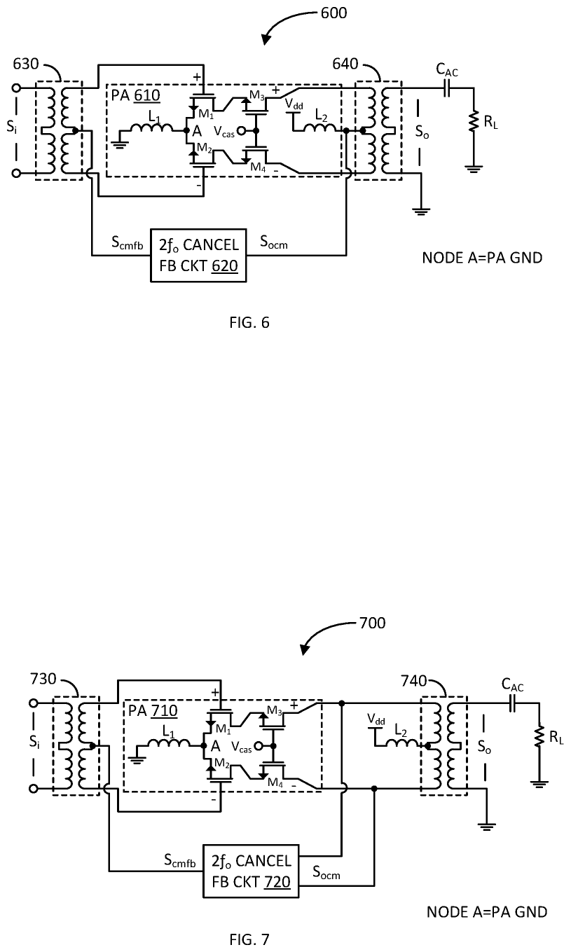

FIG. 6 illustrates a block diagram of another example power amplifier (PA) circuit 600 in accordance with another aspect of the disclosure. The PA circuit 600 may be an example implementation of PA circuits 300 and 400 previously discussed. For example, the PA circuit 600 may be similar to PA circuit 400 including an input transformer (e.g., balun) 630 with primary and secondary windings, an output transformer (e.g., balun) 640 including primary and secondary windings, and a second harmonic cancellation feedback circuit 620 including the common mode sense coupling to the output transformer 640 and the common mode injection coupling to the input transformer 630, as previously discussed.

In this example, the PA circuit 600 includes a more detailed example implementation of a differential power amplifier (PA) 610. It shall be understood that the PA 610 may be implemented in other manners. The PA 610 includes differential input transistors M₁ and M₂ (e.g., field effect transistors (FETs)), or more specifically, n-channel metal oxide semiconductor FETs (e.g., NMOS FETs)). The FETs M₁ and M₂ include gates coupled to opposite ends of the secondary winding (SW) of the input transformer 630. The PA 610 further includes a first inductor L₁ coupled between PA ground (e.g., node “A”, to which sources of the FETs M₁ and M₂ are coupled) and actual ground. The first inductor L₁ substantially isolates the RF signal of the PA 610 from actual ground, while providing a direct current (DC) current path from the FETs M₁ and M₂ to actual ground.

Additionally, the PA 610 includes a pair of cascode transistors (e.g., FETs) M₃ and M₄ including sources coupled to drains of the input differential FETs M₁ and M₂, respectively. The cascode FETs M₃ and M₄ include gates coupled together and configured to receive a cascode bias voltage V_{cas}. Further, the PA 610 includes a second inductor L₂ coupled between an upper voltage rail V_{dd} and drains of the cascode FETs M₃ and M₄ via the intermediate tap and opposite ends of the primary winding (PW) of the output transformer 640, respectively. The second inductor L₂ substantially isolates the RF signal of the PA 610 from the upper voltage rail V_{dd}, while providing a DC current path from the upper voltage rail V_{dd} to FETs M₃ and M₄.

FIG. 7 illustrates a block diagram of another example power amplifier (PA) circuit 700 in accordance with another aspect of the disclosure. The PA circuit 700 may be an example implementation of the PA circuit 300 previously discussed. The PA circuit 700 may also be a variation of PA circuit 600 with a different common mode sense circuit configuration. Thus, components of the PA circuit 700 that are same/similar to corresponding components of PA circuit 600 previously discussed in detail are numbered the same with the exception that the most significant digit is a “7” in PA circuit 700 instead of a “6” in PA circuit 600.

Accordingly, instead of the common mode sense circuit including a coupling of the input of the second harmonic cancellation feedback circuit 620 to the intermediate tap of the primary winding (PW) of the output transformer 640 to sense the output common mode signal (e.g., voltage) S_{ocm} of the output RF signal Sₒ, the second harmonic cancellation feedback circuit 720 of PA circuit 700 includes a differential input coupled to the differential output (+/−) of the differential PA 710 to sense (e.g., by voltage sensing) the output common mode signal S_{ocm}. The differential connection may allow the second harmonic cancellation feedback circuit 720 to sense the output common mode signal S_{ocm} with improved accuracy compared to the center tap approach of PA circuit 600, where winding tolerances and magnetic interference may introduce error in the sensing of the output common mode signal S_{ocm}.

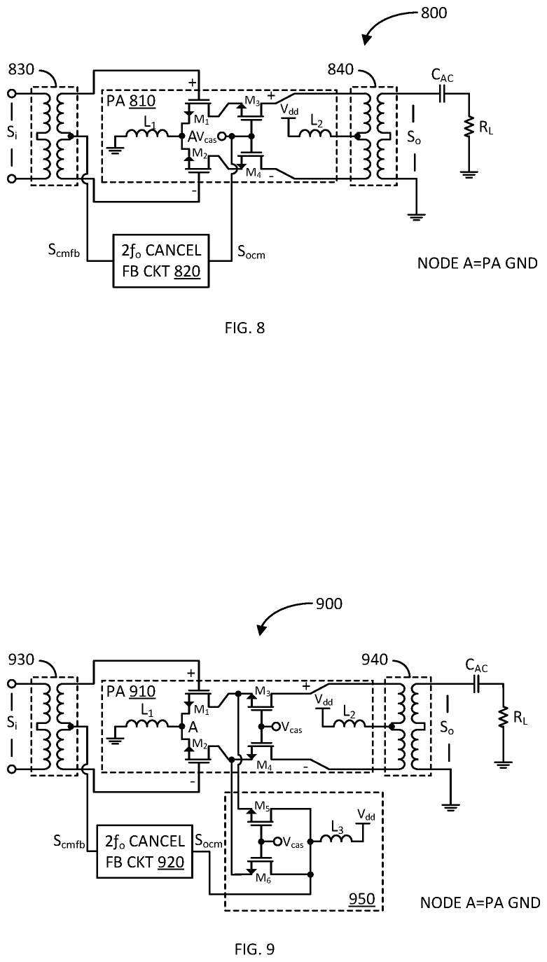

FIG. 8 illustrates a block diagram of another example power amplifier (PA) circuit 800 in accordance with another aspect of the disclosure. The PA circuit 800 may be an example implementation of the PA circuit 300 previously discussed. The PA circuit 800 may also be a variation of PA circuit 600 with a different common mode sense circuit configuration. Thus, components of the PA circuit 800 that are same/similar to corresponding components of PA circuit 600 previously discussed in detail are numbered the same with the exception that the most significant digit is a “8” in PA circuit 800 instead of a “6” in PA circuit 600.

Accordingly, instead of the common mode sense circuit including a coupling of the input of the second harmonic cancellation feedback circuit 620 to the intermediate tap of the primary winding (PW) of the output transformer 640 to sense the output common mode signal (e.g., voltage) S_{ocm} of the output RF signal Sₒ, the second harmonic cancellation feedback circuit 820 includes an input coupled to the gates of the cascode FETs M₃ and M₄ of the differential PA 810 to sense (e.g., by voltage sensing) the output common mode signal S_{ocm}. The cascode gate connection may facilitate routing to the second harmonic cancellation feedback circuit 820 for sensing of the output common mode signal S_{ocm} compared to the center tap approach of PA circuit 600 and the differential connection approach of PA circuit 700.

FIG. 9 illustrates a block diagram of another example power amplifier (PA) circuit 900 in accordance with another aspect of the disclosure. The PA circuit 900 may be an example implementation of the PA circuit 300 previously discussed. The PA circuit 900 may also be a variation of PA circuit 600 with a different common mode sense circuit configuration. Thus, components of the PA circuit 900 that are same/similar to corresponding components of PA circuit 600 previously discussed in detail are numbered the same with the exception that the most significant digit is a “9” in PA circuit 900 instead of a “6” in PA circuit 600.

Accordingly, the PA circuit 900 includes a common mode sense circuit 950 that employs current sensing (e.g., in contrast to the other common mode sense configurations that employ voltage sensing) to sense the output common mode signal S_{ocm}. More specifically, the common mode sense circuit 950 includes a pair of current-sensing transistors (e.g., FETs or NMOS FETs) M₅ and M₆ including sources coupled to the sources of the cascode FETs M₃ and M₄, respectively. The current-sensing FETs M₅ and M₆ include gates coupled together and to the gates of the cascode FETs M₃ and M₄ to also receive the cascode bias voltage V_{cas}.

Accordingly, as the gate-to-source voltages V_{gs} of the current-sensing FETs M₅ and M₆ may be the same as the gate-to-source voltages V_{gs} of the cascode FETs M₃ and M₄, the currents through the current-sensing FETs M₅ and M₆ are related to the currents through the cascode FETs M₃ and M₄ (i.e., common mode current sensing), respectively. The common mode sense circuit 950 further includes an inductor L₃ coupled between an upper voltage V_{dd} and drains of the current-sensing FETs M₅ and M₆. The common mode sense circuit 950 is configured to sense and generate the output common mode signal S_{ocm} at the drains of the current-sensing FETs M₅ and M₆.

FIG. 10 illustrates a block diagram of another example power amplifier (PA) circuit 1000 in accordance with another aspect of the disclosure. The PA circuit 1000 may be an example implementation of the PA circuit 300 previously discussed. The PA circuit 1000 may also be a variation of PA circuit 600 with a different common mode injection circuit configuration. Thus, components of the PA circuit 1000 that are same/similar to corresponding components of PA circuit 600 previously discussed in detail are numbered the same with the exception that the most significant digit is a “10” in PA circuit 1000 instead of a “6” in PA circuit 600.

Accordingly, the PA circuit 1000 includes a common mode injection circuit 1050 that employs current injection (e.g., in contrast to the other common mode injection configurations that employ voltage injection) to inject the common mode feedback signal S_{cmfb} into internal differential nodes of the PA 1010. More specifically, the common mode injection circuit 1050 includes a pair of current-injection transistors (e.g., FETs or NMOS FETs) M₅ and M₆ including drains coupled to the sources (e.g., internal differential nodes of the PA 1010) of the cascode FETs M₃ and M₄, respectively. The current-injection FETs M₅ and M₆ include gates coupled together and configured to receive the common mode feedback signal S_{cmfb} from the second harmonic cancellation feedback circuit 1020. As the common mode feedback signal S_{cmfb} control the currents through the current-injection FETs M₅ and M₆, and the drains of the current-injection FETs M₅ and M₆ are coupled to the sources of the cascode FETs M₃ and M₄, the current-injection FETs M₅ and M₆ operate as current sinks to effectively inject the common mode feedback signal S_{cmfb} into the internal differential nodes (e.g., sources of FETs M₃ and M₄) of the PA 1010.

It shall be understood that any of the PA circuits 200 to 1000 may employ any combination of the common mode voltage and/or current sensing and injection described herein.

FIG. 11 illustrates a block diagram of an example wireless communication device 1100 in accordance with another aspect of the disclosure. The wireless communication device 1100 may be implemented in a transmitter (without an associated receiver), or a transceiver including associated transmitter and receiver. Further, the wireless communication device 1100 may employ any of the power amplifier (PA) circuits described herein.

In particular, the wireless communication device 1100 includes a modem 1110, one or more frequency upconverting stage(s) 1120, one or more local oscillator(s) 1130, optionally one or more frequency downconverting stage(s) 1150, a radio frequency (RF) front end 1160, and at least one antenna 1170 (e.g., an antenna array). The RF front end 1160, in turn, includes a power amplifier (PA) circuit 1162, optionally a transmitter-receiver (TX-RX) isolation device 1166 (e.g., a switch, filter, circulator, etc.), and optionally a low noise amplifier (LNA) 1168. As mentioned, the PA circuit 1162 may be implemented per any PA circuit described herein for second harmonic reduction purposes as previously discussed.

With regard to signal transmission, the modem 1110 is configured to generate a transmit baseband signal D_{TXBB}. The one or more frequency upconverting stage(s) is configured to frequency upconvert the transmit baseband signal D_{TXBB} (e.g., from baseband (BB) to radio frequency (RF) directly or via one or more intermediate frequencies (IFs)) using one or more transmit local oscillator signal(s) V_{TXLO} generated by the one or more local oscillator(s) 1130 to generate a transmit RF signal V_{TXRF}. With reference to the previously-described PA circuits 200-1000, the transmit radio frequency signal V_{TXRF} may serve as the input RF signal Sᵢ for the PA circuit 1162. The PA circuit 1162 is configured to amplify the transmit radio frequency signal V_{TXRF} to generate an output RF signal Sₒ while employing the second harmonic cancellation circuit as described herein. The output RF signal Sₒ is provided to the at least one antenna 1170 via the TX-RX isolation device 1166. The at least one antenna 1170 is configured to wirelessly radiate the output RF signal Sₒ.

With regard to optional signal reception, the at least one antenna 1170 may wirelessly sense/pickup a received RF signal V_{RXRF}, which may be low noise amplified by the LNA 1168. The one or more frequency downconverting stage(s) is configured to frequency downconvert the received RF signal V_{RXRF} (e.g., from RF to BB directly or via one or more IFs) using one or more received local oscillator signal(s) V_{RXLO} generated by the one or more local oscillator(s) 1130 to generate a received BB signal D_{RXBB}. The modem 1110 may receive and process the received BB signal D_{RXBB} to extract and/or recover information or data therein.

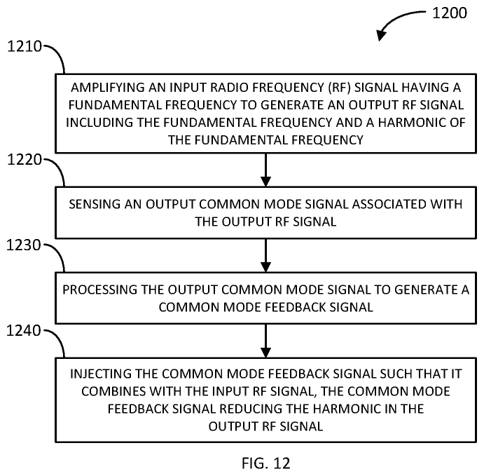

FIG. 12 illustrates a flow diagram of an example method 1200 of reducing a harmonic constituent of an output radio frequency (RF) signal of a power amplifier (PA) in accordance with another aspect of the disclosure. The method 1200 includes amplifying an input radio frequency (RF) signal including a fundamental frequency to generate an output RF signal including the fundamental frequency and a harmonic of the fundamental frequency (block 1210). Examples of means for amplifying an input radio frequency (RF) signal including a fundamental frequency to generate an output RF signal including the fundamental frequency and a harmonic of the fundamental frequency includes any of the power amplifiers (PAs) 210 to 1010 described herein.

The method 1200 further includes sensing an output common mode signal associated with the output RF signal (block 1220). Examples of means for sensing an output common mode signal associated with the output RF signal including any of the common mode sensing or coupling configuration described herein (e.g., via an intermediate tap of the primary winding of the output transformers in PA circuits 400, 600, and 1000, via a node between output capacitors coupled across the differential output of the PA 510 in PA circuit 500, via the differential output of the PA 710 in PA circuit 700, via the gates of cascode transistors of the PA 810 in PA circuit 800, via sensing currents through cascode transistors of the PA 910 in PA circuit 900).

The method 1200 further includes processing the output common mode signal to generate a common mode feedback signal (block 1230). Examples of means for processing the output common mode signal to generate a common mode feedback signal include any of the second harmonic cancellation feedback circuits 220, 310, 330, 350, 370, and 420 to 1020 described herein. Additionally, the method 1200 includes injecting the common mode feedback signal such that it combines with the input RF signal, the common mode feedback signal reducing the harmonic in the output RF signal (block 1240). Examples of means for injecting the common mode feedback signal so that it combines with the input RF signal include any of the common mode injection circuit or coupling configuration described herein (e.g., via an intermediate tap of the secondary winding of the input transformer in PA circuits 400 to 900, or the common mode current injection circuit 1050 in PA circuit 1000.

The following provides an overview of aspects of the present disclosure:

Aspect 1: An apparatus, comprising: an amplifier configured to amplify an input radio frequency (RF) signal having a fundamental frequency to generate an output RF signal including the fundamental frequency and a harmonic of the fundamental frequency; a common mode sense circuit configured to generate an output common mode signal related to the output RF signal; a harmonic cancellation feedback circuit configured to generate a common mode feedback signal based on the output common mode signal; and a common mode injection circuit configured to inject the common mode feedback signal into the amplifier, wherein the common mode feedback signal reduces the harmonic in the output RF signal.

Aspect 2: The apparatus of aspect 1, wherein the harmonic cancellation feedback circuit includes a phase shifter configured to apply a phase shift to the output common mode signal.

Aspect 3: The apparatus of aspect 2, wherein the phase shifter comprises a right-hand transmission-line (RHTL) phase shifter.

Aspect 4: The apparatus of aspect 2, wherein the phase shifter comprises a left-hand transmission-line (LHTL) phase shifter.

Aspect 5: The apparatus of any one of aspects 1-4, wherein the harmonic cancellation feedback circuit includes a filter configured to substantially reduce the fundamental frequency and pass the harmonic to generate the common mode feedback signal.

Aspect 6: The apparatus of aspect 5, wherein the filter comprises a band pass filter (BPF) or a high pass filter (HPF).

Aspect 7: The apparatus of any one of aspects 1-6, further comprising a transformer including a primary winding coupled across a differential output of the amplifier, wherein the common mode sense circuit includes a coupling of an intermediate tap of the primary winding to an input of the harmonic cancellation feedback circuit.

Aspect 8: The apparatus of any one of aspects 1-6, further comprising first and second capacitors coupled in series across a differential output of the amplifier, wherein the common mode sense circuit includes a coupling of a node between the first and second capacitors to an input of the harmonic cancellation feedback circuit.

Aspect 9: The apparatus of any one of aspects 1-6, wherein the common mode sense circuit includes a coupling of a differential output of the amplifier to a differential input of the harmonic cancellation feedback circuit.

Aspect 10: The apparatus of any one of aspects 1-6, wherein the amplifier comprises: a differential pair of field effect transistors (FETs); and a pair of cascode FETs coupled in series with the differential pair of FETs between an upper voltage rail and ground, respectively; wherein the common mode sense circuit includes a coupling of gates of the pair of cascode FETs to an input of the harmonic cancellation feedback circuit.

Aspect 11: The apparatus of claim 1, wherein the amplifier comprises: a differential pair of field effect transistors (FETs); and a pair of cascode FETs coupled in series with the differential pair of FETs between an upper voltage rail and ground, respectively; wherein the common mode sense circuit comprises a pair of current-sensing FETs including sources and gates coupled to sources and gates of the pair of cascode FETs, respectively, and drains coupled to an input of the harmonic cancellation feedback circuit.

Aspect 12: The apparatus of any one of aspects 1-11, further comprising a transformer including a primary winding configured to receive the input RF signal and a secondary winding coupled across a differential input of the amplifier, wherein the common mode injection circuit includes a coupling of an output of the harmonic cancellation feedback circuit to an intermediate tap of the secondary winding.

Aspect 13: The apparatus of any one of aspects 1-11, wherein the amplifier comprises: a differential pair of field effect transistors (FETs); and a pair of cascode FETs coupled in series with the differential pair of FETs between an upper voltage rail and ground, respectively; wherein the common mode injection circuit comprises a pair of FETs including drains coupled to sources of the pair of cascode FETs, respectively, and gates coupled to an output of the harmonic cancellation feedback circuit.

Aspect 14: The apparatus of any one of aspects 1-13, wherein the harmonic comprises one or more even harmonics of the fundamental frequency.

Aspect 15: The apparatus of any one of aspects 1-13, wherein the harmonic comprises a second harmonic of the fundamental frequency.

Aspect 16: The apparatus of any one of aspects 1-15, wherein the amplifier comprises a power amplifier (PA) or a driver amplifier.

Aspect 17: A method comprising: amplifying an input radio frequency (RF) signal having a fundamental frequency to generate an output RF signal including the fundamental frequency and a harmonic of the fundamental frequency; sensing an output common mode signal associated with the output RF signal; processing the output common mode signal to generate a common mode feedback signal; and injecting the common mode feedback signal such that it combines with the input RF signal, the common mode feedback signal reducing the harmonic in the output RF signal.

Aspect 18: The method of aspect 17, wherein processing the output common mode signal comprises phase shifting the output common mode signal.

Aspect 19: The method of aspect 17 or 18, wherein processing the output common mode signal comprises filtering the output common mode signal.

Aspect 20: The method of any one of aspects 17-19, wherein sensing the output common mode signal comprises sensing the output common mode signal via an intermediate tap of a primary winding of a transformer across which the output RF signal is generated.

Aspect 21: The method of any one of aspects 17-19, wherein sensing the output common mode signal comprises sensing the output common mode signal via a node between two output capacitors across which the output RF signal is generated.

Aspect 22: The method of any one of aspects 17-19, wherein sensing the output common mode signal comprises sensing the output common mode signal across a differential output of an amplifier across which the output RF signal is generated.

Aspect 23: The method of any one of aspects 17-19, wherein sensing the output common mode signal comprises sensing the output common mode signal at gates of cascode transistors of an amplifier.

Aspect 24: The method of any one of aspects 17-19, wherein sensing the output common mode signal comprises sensing a differential current generated within an amplifier generating the output RF signal.

Aspect 25: The method of any one of aspects 17-24, wherein injecting the common mode feedback signal comprises injecting the common mode feedback signal via an intermediate tap of a secondary winding of a transformer, the transformer including a primary winding across which the input RF signal is applied.

Aspect 26: The method of any one of aspects 17-24, wherein injecting the common mode feedback signal comprises sinking differential current from the amplifier based on the common mode feedback signal.

Aspect 27: An apparatus, comprising: means for amplifying an input radio frequency (RF) signal having a fundamental frequency to generate an output RF signal including the fundamental frequency and a harmonic of the fundamental frequency; means for sensing an output common mode signal associated with the output RF signal; means for processing the output common mode signal to generate a common mode feedback signal; and means for injecting the common mode feedback signal such that it combines with the input RF signal, the common mode feedback signal reducing the harmonic in the output RF signal.

Aspect 28: A wireless communication device, comprising: a modem configured to generate a transmit baseband signal; a local oscillator (LO) configured to generate one or more transmit LO signals; one or more frequency upconverting stages configured to frequency upconvert the transmit baseband signal to generate a transmit radio frequency (RF) signal based on the one or more transmit LO signals, respectively; an amplifier configured to amplify the transmit RF signal having a fundamental frequency to generate a transmit output RF signal including the fundamental frequency and a harmonic of the fundamental frequency; a common mode sense circuit configured to generate an output common mode signal related to the transmit output RF signal; a harmonic cancellation feedback circuit configured to generate a common mode feedback signal based on the output common mode signal; a common mode injection circuit configured to inject the common mode feedback signal into the amplifier, wherein the common mode feedback signal reduces the harmonic in the transmit output RF signal; and at least one antenna configured to wirelessly radiate the transmit output RF signal.

Aspect 29: The wireless communication device of aspect 28, wherein the at least one antenna is configured to wirelessly sense a received radio frequency (RF) signal, wherein the LO is configured to generate one or more received LO signals, and further comprising: a low noise amplifier (LNA) configured to amplify a received RF signal; and one or more frequency downconverting stages configured to frequency downconvert the received RF signal to generate a received baseband signal based on the one or more LO signals, respectively; wherein the modem is configured to process the received baseband signal to extract or recover data and/or information therein.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed:

1. An apparatus, comprising:
an amplifier configured to amplify an input radio frequency (RF) signal having a fundamental frequency to generate an output RF signal including the fundamental frequency and a harmonic of the fundamental frequency;
a common mode sense circuit configured to generate an output common mode signal related to the output RF signal;
a harmonic cancellation feedback circuit configured to generate a common mode feedback signal based on the output common mode signal; and
a common mode injection circuit configured to inject the common mode feedback signal into the amplifier, wherein the common mode feedback signal reduces the harmonic in the output RF signal.

2. The apparatus of claim 1, wherein the harmonic cancellation feedback circuit includes a phase shifter configured to apply a phase shift to the output common mode signal.

3. The apparatus of claim 2, wherein the phase shifter comprises a right-hand transmission-line (RHTL) phase shifter.

4. The apparatus of claim 2, wherein the phase shifter comprises a left-hand transmission-line (LHTL) phase shifter.

5. The apparatus of claim 1, wherein the harmonic cancellation feedback circuit includes a filter configured to substantially reduce the fundamental frequency and pass the harmonic to generate the common mode feedback signal.

6. The apparatus of claim 5, wherein the filter comprises a band pass filter (BPF) or a high pass filter (HPF).

7. The apparatus of claim 1, further comprising a transformer including a primary winding coupled across a differential output of the amplifier, wherein the common mode sense circuit includes a coupling of an intermediate tap of the primary winding to an input of the harmonic cancellation feedback circuit.

8. The apparatus of claim 1, further comprising first and second capacitors coupled in series across a differential output of the amplifier, wherein the common mode sense circuit includes a coupling of a node between the first and second capacitors to an input of the harmonic cancellation feedback circuit.

9. The apparatus of claim 1, wherein the common mode sense circuit includes a coupling of a differential output of the amplifier to a differential input of the harmonic cancellation feedback circuit.

10. The apparatus of claim 1, wherein the amplifier comprises:
a differential pair of field effect transistors (FETs); and
a pair of cascode FETs coupled in series with the differential pair of FETs between an upper voltage rail and ground, respectively;
wherein the common mode sense circuit includes a coupling of gates of the pair of cascode FETs to an input of the harmonic cancellation feedback circuit.

11. The apparatus of claim 1, wherein the amplifier comprises:
a differential pair of field effect transistors (FETs); and
a pair of cascode FETs coupled in series with the differential pair of FETs between an upper voltage rail and ground, respectively;
wherein the common mode sense circuit comprises a pair of current-sensing FETs including sources and gates coupled to sources and gates of the pair of cascode FETs, respectively, and drains coupled to an input of the harmonic cancellation feedback circuit.

12. The apparatus of claim 1, further comprising a transformer including a primary winding configured to receive the input RF signal and a secondary winding coupled across a differential input of the amplifier, wherein the common mode injection circuit includes a coupling of an output of the harmonic cancellation feedback circuit to an intermediate tap of the secondary winding.

13. The apparatus of claim 1, wherein the amplifier comprises:
a differential pair of field effect transistors (FETs); and
a pair of cascode FETs coupled in series with the differential pair of FETs between an upper voltage rail and ground, respectively;
wherein the common mode injection circuit comprises a pair of FETs including drains coupled to sources of the pair of cascode FETs, respectively, and gates coupled to an output of the harmonic cancellation feedback circuit.

14. The apparatus of claim 1, wherein the harmonic comprises one or more even harmonics of the fundamental frequency.

15. The apparatus of claim 1, wherein the harmonic comprises a second harmonic of the fundamental frequency.

16. The apparatus of claim 1, wherein the amplifier comprises a power amplifier (PA) or a driver amplifier.

17. A method, comprising:
amplifying an input radio frequency (RF) signal having a fundamental frequency to generate an output RF signal including the fundamental frequency and a harmonic of the fundamental frequency;
sensing an output common mode signal associated with the output RF signal;
processing the output common mode signal to generate a common mode feedback signal; and
injecting the common mode feedback signal such that it combines with the input RF signal, the common mode feedback signal reducing the harmonic in the output RF signal.

18. The method of claim 17, wherein sensing the output common mode signal comprises sensing the output common mode signal via an intermediate tap of a primary winding of a transformer across which the output RF signal is generated.

19. The method of claim 17, wherein injecting the common mode feedback signal comprises injecting the common mode feedback signal via an intermediate tap of a secondary winding of a transformer, the transformer including a primary winding across which the input RF signal is applied.

20. A wireless communication device, comprising:
a modem configured to generate a transmit baseband signal;
a local oscillator (LO) configured to generate one or more transmit LO signals;
one or more frequency upconverting stages configured to frequency upconvert the transmit baseband signal to generate a transmit radio frequency (RF) signal based on the one or more transmit LO signals, respectively;
an amplifier configured to amplify the transmit RF signal having a fundamental frequency to generate a transmit output RF signal including the fundamental frequency and a harmonic of the fundamental frequency;
a common mode sense circuit configured to generate an output common mode signal related to the transmit output RF signal;
a harmonic cancellation feedback circuit configured to generate a common mode feedback signal based on the output common mode signal;
a common mode injection circuit configured to inject the common mode feedback signal into the amplifier, wherein the common mode feedback signal reduces the harmonic in the transmit output RF signal; and
at least one antenna configured to wirelessly radiate the transmit output RF signal.
